(19) United States
(12) Patent Application Publication
(10) Pub. No.: US 2025/0336648 A1
(43) Pub. Date: Oct. 30, 2025

(54) GAS SUPPLY APPARATUS AND PLASMA PROCESSING APPARATUS

(71) Applicant: Panasonic Intellectual Property Management Co., Ltd., Osaka (JP)

(72) Inventors: Shogo OKITA, HYOGO (JP); Takahiro MIYAI, OSAKA (JP); Toshihiro WADA, OSAKA (JP); Toshiyuki TAKASAKI, OSAKA (JP)

(21) Appl. No.: 19/185,727

(22) Filed: Apr. 22, 2025

(30) Foreign Application Priority Data
Apr. 26, 2024 (JP) 2024-072781

(51) Int. Cl. H01J 37/32

(52) U.S. Cl. CPC H01J 37/32449; H01J 2237/334

(57) ABSTRACT

A gas supply apparatus includes: supply source pipes; upstream pipes branched from the supply source pipes and corresponding to supply points in a chamber; flow rate controllers provided in the respective upstream pipes, midstream pipes branched from the upstream pipes and corresponding to processing steps performed in the chamber; valves provided in the respective midstream pipes; downstream pipes into which midstream pipes corresponding to the same supply point and the same processing step merge; outflow pipes which are connected to downstream pipes corresponding to the same supply point through a switching section, and each of which is connected to one of the supply points; and a control unit that controls the switching section so that the downstream pipes in fluid communication with the outflow pipes are switched according to the processing steps.

### CROSS REFERENCE TO RELATED APPLICATION

The present application is based on and claims priority under 35 U.S.C. § 119 with respect to the Japanese Patent Application No. 2024-072781 filed on Apr. 26, 2024, of which entire content is incorporated herein by reference into the present application.

### TECHNICAL FIELD

The present disclosure relates to a gas supply apparatus and a plasma processing apparatus.

### BACKGROUND

Conventionally, gas supply apparatuses that supply a processing gas to a chamber in which plasma processing is performed have been known (e.g., Japanese Laid-Open Patent Publication No. 2020-4931). The gas supply apparatus disclosed in Japanese Laid-Open Patent Publication No. 2020-4931 includes a first gas supply pipe for supplying a first processing gas to the central part of the chamber, a second gas supply pipe for supplying the first processing gas to the outer peripheral part in the chamber, a third gas supply pipe for supplying a second processing gas to the central part of the chamber, and a fourth supply pipe for supplying the second processing gas to the outer peripheral part in the chamber, wherein plasma processing using the first processing gas and plasma processing using the second processing gas are selectively performed by setting each of the first gas supply pipe and the second gas supply pipe, or each of the third gas supply pipe and the fourth gas supply pipe, to an open state while setting each of the other pipes to a closed state. Each of the first to fourth gas supply pipes is provided with a flow rate control valve capable of adjusting a degree of opening.

As described above, a flow rate control valve is provided in each of the first to fourth gas supply pipes in the gas supply apparatus in Japanese Laid-Open Patent Publication No. 2020-4931. The number of first to fourth gas supply pipes or the number of the flow control valves (here, four) is equal to the product of the number of the types of the processing gases (here, two) and the number of processing gas supply areas (here, two areas of the central part and the outer peripheral part in the chamber). This is equivalent to placement of the flow control valves one at each point where flow control is desired. However, since the flow rate control valves are relatively expensive components, it is desirable to reduce the number thereof as much as possible in view of reducing the production cost of the gas supply apparatus. Nevertheless, if the number of the flow rate control valves is simply reduced, a desired function of the gas supply apparatus, for example, a function of high-speed processing gas switching may not be achieved.

### SUMMARY

One aspect of the present disclosure relates to a gas supply device. The gas supply apparatus includes: a plurality of supply source pipes through which processing gases flows; a plurality of upstream pipes branched from the supply source pipes and corresponding to a plurality of supply points in the chamber; a plurality of flow rate controllers provided in the respective upstream pipes; a plurality of midstream pipes branched from the upstream pipes and corresponding to a plurality of processing steps performed in the chamber; a plurality of valves provided in the respective midstream pipes; a plurality of downstream pipes into which midstream pipes of the midstream pipes corresponding to a same supply point of the supply points and a same processing step of the processing steps merge; a plurality of outflow pipes connected to downstream pipes of the downstream pipes corresponding to a same supply point of the supply points through a switching section, the outflow pipes each being connected to one of the supply points; and a control unit that controls the switching section so that downstream pipes of the downstream pipes in fluid communication with the plurality of outflow pipes are switched according to the processing steps.

Another aspect of the present disclosure relates to a plasma processing apparatus. The plasma processing apparatus includes a chamber in which plasma processing is performed, and the above-described gas supply apparatus that supplies the processing gases to the chamber.

### BRIEF DESCRIPTION OF THE DRAWINGS

FIG. 1 is a schematic configuration diagram illustrating an example of a plasma processing apparatus according to the present disclosure.

FIG. 2 is a schematic configuration diagram illustrating processing gas flow under first control.

FIG. 3 is a schematic configuration diagram illustrating processing gas flow under second control.

### DETAILED DESCRIPTION

The following describes embodiments of a gas supply apparatus and a plasma processing apparatus according to the present disclosure by way of examples. However, the present disclosure is not limited to the embodiments described below. In the following description, specific numerical values and materials may be exemplified in some cases, but other numerical values and other materials may be adopted as long as the effects of the present disclosure can be obtained.

### Gas Supply Apparatus

The gas supply apparatus according to the present disclosure is an apparatus for supplying processing gases to a chamber in which plasma processing is performed. The gas supply apparatus according to the present disclosure includes a plurality of supply source pipes, a plurality of upstream pipes, a plurality of flow rate controllers, a plurality of midstream pipes, a plurality of valves, a plurality of downstream pipes, a plurality of outflow pipes, and a control unit.

The processing gases flow through the plurality of supply source pipes. Each of the supply source pipes may be connected to a gas source that supplies the processing gases. The processing gases may be processing gases for plasma processing (e.g., plasma etching). The supply source pipes may each allow a single processing gas to flow therein. The number of the supply source pipes is not particularly limited, and may be the same number as the number of types of the processing gases used for the plasma processing, for example.

The plurality of upstream pipes are branched from the supply source pipes. The plurality of upstream pipes correspond to a plurality of supply points in the chamber. The plurality of upstream pipes may each be branched from one of the supply source pipes or some of the supply source pipes. For example, in a case where there are two types of supply points in the chamber, two upstream pipes may be branched from a single supply source pipe. The supply source pipes and the plurality of upstream pipes may be connected to one another via supply source pipe branch points. In other words, the supply source pipes may each be branched into a plurality of (e.g., two) upstream pipes at a supply source pipe branch point. The plasma processing may be performed inside the chamber. The plurality of supply points may include a supply point at central part and a supply point at the outer peripheral part, for example. The number of the supply points and the number of the upstream pipes corresponding thereto are not particularly limited, and may be two or more and four or less, for example.

The plurality of flow rate controllers are provided in the respective upstream pipes. For example, the flow rate controllers may be provided one in each of the upstream pipes. Each of the flow rate controllers may control the flow rate of the processing gas flowing through the upstream pipe in which the flow rate controller is provided. The flow rate controllers may each be composed of a mass flow rate controller (MFC), for example. The operation of each flow rate controller may be controlled by the control unit.

The plurality of midstream pipes are branched from the upstream pipes. The plurality of midstream pipes correspond to a plurality of processing steps performed in the chamber. The plurality of midstream pipes may be branched from one of the upstream pipes or some of the upstream pipes. For example, in a case where two processing steps are performed in the chamber, two midstream pipes may be branched off from a single upstream pipe. The upstream pipes and the plurality of midstream pipes may be connected to one another via upstream pipe branch points. In other words, the upstream pipe may each be branched into a plurality of (e.g., two) midstream pipes at an upstream pipe branch point. The plurality of processing steps may be regarded as two processing steps, according to the types of the processing gas used in the steps. For example, in a case where there are two processing steps mainly using a first processing gas and two processing steps mainly using a second processing gas, the former two processing steps may be regarded as a first processing step and the latter two processing steps may be regarded as a second processing step. In such a case, “a plurality of processing steps” may be read as “two processing steps”. However, this replacement does not preclude the presence of three or more processing steps.

The plurality of valves are provided in the respective midstream pipes. For example, the valves may be provided one in each of the midstream pipes. Each of the valves may allow and stop the flow of the corresponding processing gas in the midstream pipe in which the valve is provided. The valves may each be composed of an openable and closable solenoid valve, for example. The operation of each valve may be controlled by the control unit.

Into the plurality of downstream pipes, midstream pipes corresponding to the same supply point and the same processing steps merge. For example, in a case where two types of supply points are present at the central part and the outer peripheral part of the chamber and two processing steps are performed in the chamber: a plurality of midstream pipes corresponding to the supply point at the central part and one of the processing steps may merge into one of the downstream pipes; a plurality of midstream pipes corresponding to the supply point at the central part and the other of the processing steps may merge into another downstream pipe; a plurality of midstream pipes corresponding to the supply point at outer peripheral part and the one processing step may merge into still another downstream pipe; and a plurality of midstream pipes corresponding to the supply point at the outer peripheral part and the other processing step may merge into yet another downstream pipe. Each of the midstream pipes and a corresponding one of the downstream pipes may be connected to each other via a single junction. In other words, the midstream pipes may each be merged to be connected to a corresponding one of the downstream pipes by junctions.

The plurality of outflow pipes are each connected to one of the downstream pipes that corresponds to the same supply point through switching sections. Each of the plurality of outflow pipes is connected to one of the supply points. For example, in a case where there are two types of supply points, one at the central part and the other at the outer peripheral part of the chamber, one of the outflow pipes may be connected to a plurality of downstream pipes corresponding to the supply point at the central part through one of the switching sections, and the other outflow pipe may be connected to a plurality of downstream pipes corresponding to the supply point at the outer peripheral part through the other of the switching sections. The switching sections may cause one of the plurality of downstream pipes connected thereto to be exclusively connected to the outflow pipe connected thereto.

The control unit controls the switching sections to switch the downstream pipes in fluid communication with the plurality of outflow pipes according to the processing steps. For example, in a case where two processing steps are performed in the chamber, the control unit may control the switching sections such that the downstream pipes corresponding to one of the processing steps are in fluid communication with the outflow pipes and the downstream pipes corresponding to the other processing step are not in fluid communication with the outflow pipes. The control unit may include an arithmetic unit and a storage device that stores therein a program executable by the arithmetic unit.

In the gas supply apparatus having the above configuration, each of the processing gases flows through a supply source pipe, an upstream pipe, a midstream pipe, a downstream pipe, and an outflow pipe in the stated order and flows out into the chamber. When the processing gas flows from one supply source pipe to a plurality of upstream pipes, the processing gas is distributed correspondingly the plurality of supply points in the chamber. In each upstream pipe, the flow rate of the processing gas is controlled by the corresponding flow rate controller. Thereafter, when the processing gas flows from one upstream pipe to a plurality of midstream pipes, the processing gas is further distributed correspondingly to the plurality of processing steps performed in the chamber. Thereafter, the processing gas flows from at least one midstream pipe corresponding to a valve in the open state to a downstream pipe, and flows from the downstream pipe into an outflow pipe through a switching section. The processing gas then flows through the outflow pipe and into the chamber, where it is supplied for plasma processing. Processing gas switching is performed by the switching sections located near the chamber. In the above configuration, the processing gas supplied after the switching is mixed only with another processing gas remaining between a corresponding switching section and the chamber, that is, in a corresponding outflow pipe. Thus, the processing gas switching can be performed at high speed. In addition, pressure fluctuations during the switching in the chamber can be suppressed.

In order to finely control the flow rate of the processing gas, it can be generally considered to provide a flow rate controller in each midstream pipe. However, in the gas supply apparatus according to the present disclosure, the required number of the flow rate controllers is reduced without excessively impairing the flow rate controllability of the processing gases by proving the flow rate controllers in the respective upstream pipe located upstream of the midstream pipes. That is, when the flow rate controllers are provided in the respective midstream pipes, the flow rate of midstream pipes in which the processing gas before the switching flows and the flow rate of midstream pipes in which the processing gas after the switching flows can be individually controlled for processing gas switching according to the processing steps by the switching sections. As a result, desired flow rate control can be easily achieved, even immediately after the switching, by executing the latter flow rate control in advance. By contrast, provision of the flow rate controllers in the respective upstream pipes may necessitate that each flow rate controller control both the flow rate of the midstream pipe through which the processing gas before processing gas switching flows and the flow rate of the midstream pipe through which the processing gas after the switching flows. The inventor of the present application found that sufficient flow control can be done by a single flow rate controller for a plurality of midstream pipes even in such a case, since the response time of the flow rate controllers is sufficiently shorter than the time required for processing gas replacement. As such, in the present disclosure, the flow rate controllers are provided in the upstream pipes with fewer than the midstream pipes in number, rather than in the midstream pipes. This reduces the required number of the flow rate controllers, thereby reducing the production cost of the gas supply apparatus.

The plurality of supply source pipes may include a first supply source pipe through which the first processing gas flows and a second supply source pipe through which the second processing gas flows. The plurality of upstream pipes may include: a first upstream pipe and a second upstream pipe each branched from the first supply source pipe and respectively corresponding to the first supply point and a second supply point; and a third upstream pipe and a fourth upstream pipe each branched from the second supply source pipe and respectively corresponding to the first supply point and the second supply point. The plurality of flow rate controllers may include a first flow rate controller provided in the first upstream pipe, a second flow rate controller provided in the second upstream pipe, a third flow rate controller provided in the third upstream pipe, and a fourth flow rate controller provided in the fourth upstream pipe. The plurality of midstream pipes may include: a first midstream pipe and a second midstream pipe each branched from the first upstream pipe and respectively corresponding to the first processing step and the second processing step; a third midstream pipe and a fourth midstream each branched from the second upstream pipe and respectively corresponding to the first processing step and the second processing step; a fifth midstream pipe and a sixth midstream pipe each branched from the third upstream pipe and respectively corresponding to the first processing step and the second processing step; and a seventh midstream pipe and an eighth midstream pipe each branched from the fourth upstream pipe and respectively corresponding to the first processing step and the second processing step. The plurality of valves may include a first valve provided in the first midstream pipe, a second valve provided in the second midstream pipe, a third valve provided in the third midstream pipe, a fourth valve provided in the fourth midstream pipe, a fifth valve provided in the fifth midstream pipe, a sixth valve provided in the sixth midstream pipe, a seventh valve provided in the seventh midstream pipe, and an eighth valve provided in the eighth midstream pipe. The plurality of downstream pipes may include a first downstream pipe into which the first midstream pipe and the fifth midstream pipe merge, a second downstream pipe into which the second midstream pipe and the sixth midstream pipe merge, a third downstream pipe into which the third midstream pipe and the seventh midstream pipe merge, and a fourth downstream pipe into which the fourth midstream pipe and the eighth midstream pipe merge. The plurality of outflow pipes may include a first outflow pipe connected to the first downstream pipe or the second downstream pipe through a first switching section and connected to the first supply point, and a second outflow pipe connected to the third downstream pipe or the fourth downstream pipe through a second switching section and connected to the second supply point. The first switching section may be composed of a first switching valve that causes either the first downstream pipe or the second downstream pipe to be in exclusive fluid communication with the first outflow pipe. The second switching section may be composed of a second switching valve that causes either the third downstream pipe or the fourth downstream pipe to be in exclusive fluid communication with the second outflow pipe. The control unit may execute first control and second control. Under the first control: the first downstream pipe and the first outflow pipe are in fluid communication with each other through the first switching valve; the third downstream pipe and the second outflow pipe are in fluid communication with each other through the second switching valve; and the second valve, the fourth valve, the sixth valve, and the eighth valve are closed. Under the second control: the second downstream pipe and the first outflow pipe are in fluid communication with each other through the first switching valve; the fourth downstream pipe and the second outflow pipe are in fluid communication with each other through the second switching valve; and the first valve, the third valve, the fifth valve, and the seventh valve are closed. The first control may correspond to the first processing step. The second control may correspond to the second processing step. The control unit may open at least one of the first valve, the third valve, the fifth valve, and the seventh valve during the first control. The control unit may open at least one of the second valve, the fourth valve, the sixth valve, and the eighth valve during the second control. Under the first control or the second control, the first processing gas or the second processing gas may flow through the midstream pipe corresponding to the valve opened by the control unit among the first to eighth valves. Under the first control, the first processing gas may flow out into the chamber via the first downstream pipe and the first outflow pipe or via the third downstream pipe and the second outflow pipe. Under the second control, the second processing gas may flow out into the chamber via the second downstream pipe and the first outflow pipe or via the fourth downstream pipe and the second outflow pipe. In the above configuration, switching between the first control and the second control, that is, switching between the first processing gas and the second processing gas, can be executed at high speed because the first and second switching valves are located near the chamber. This high-speed switching can be achieved at low cost because the flow rate controllers are provided in the four upstream pipes instead of the eight midstream pipes.

The control unit may repeat a unit process including the first control and the second control multiple times. Repetition of the unit process multiple times as described above means repetition of the processing gas switching. This can further effectively utilize the effects obtained by the gas supply apparatus according to the present disclosure. The first control may be a control for depositing a protective film on the surface of a substrate, and the second control may be a control for etching the surface of the substrate. In this case, a generally-called Bosch process can be executed by repeating the unit process multiple times.

### Plasma Processing Apparatus

The plasma processing apparatus according to the present disclosure may be a plasma etching apparatus, a plasma cleaner, a plasma dicer, a plasma ashing apparatus, or a plasma CVD apparatus, for example. The plasma processing apparatus according to the present disclosure includes a chamber and the above-described gas supply apparatus.

Plasma processing is performed in the chamber. The plasma processing may be plasma processing on a substrate, for example. The chamber may include a base and a lid openable and closable relative to the base. The chamber may be set in a reduced pressure state by a pressure reducing mechanism (e.g., a vacuum pump) with the lid closed. Plasma is generated in the chamber in the reduced pressure state by generating a high-frequency electromagnetic field in the chamber, for example, using a high-frequency power supply and at least one coil connected thereto while supplying the processing gas into the chamber from the gas supply apparatus. Thus, the substrate placed in the chamber can be plasma-processed.

The chamber may have a plurality of supply points to which the respective outflow pipes are connected. For example, the chamber may have a first supply point at the central part in the horizontal direction and a second supply point at an outer peripheral part in the horizontal direction. Provision of a plurality of supply points as described above can enhance uniformity of the plasma processing on a processing targe (e.g., a substrate) placed in the chamber. For example, the etch rate in plasma-etching on the substrate can be made uniform throughout the substrate.

In the plasma processing apparatus according to the present disclosure, the processing gases are supplied to the chamber by the above-described gas supplying apparatus. In the above configuration, when plasma processing is performed while switching between multiple types of processing gases, the processing gases can be switched at high speed. Further, a small number of the flow rate controllers included in the gas supply apparatus suffice, with a result that the production cost of the plasma processing apparatus can be reduced.

According to the present disclosure, provision of the switching sections near the chamber as described above can achieve high-speed processing gas switching. In addition, according to the present disclosure, reducing the required number of the flow rate controllers can enable high-speed processing gas switching at a low cost.

Hereinafter, examples of a gas supply apparatus and a plasma processing apparatus each according to the present disclosure will be described in detail with reference to the drawings. The above-described constituent elements can be applied to the constituent elements in the examples of the gas supply apparatus and the plasma processing apparatus each described below. The constituent elements of the gas supply apparatus and the plasma processing apparatus of the example described below can be altered based on the above description. Further, the matters described below may be applied to the above-described embodiments. Among the constituent elements of the example of the gas supply apparatus and the plasma processing apparatus each described below, a constituent element not essential to the gas supply apparatus or the plasma processing apparatus according to the present disclosure may be omitted. It should be noted that the drawings indicated below are schematic and do not accurately reflect the shape or number of actual members.

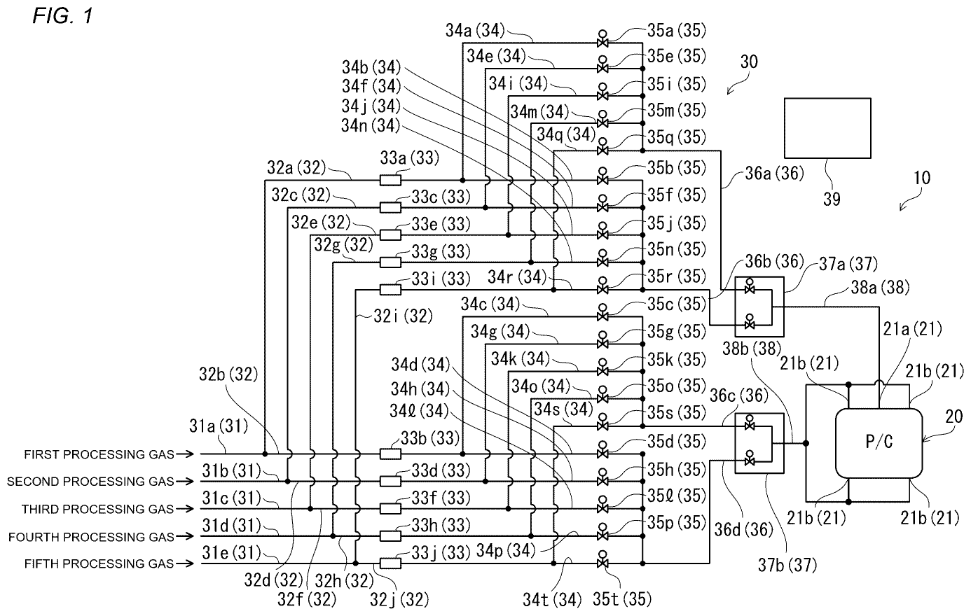

As illustrated in FIG. 1, a plasma processing apparatus 10 of the present embodiment includes a chamber 20 and a gas supply apparatus 30. The plasma processing apparatus 10 of the present embodiment is configured as a plasma etching apparatus, but is not limited thereto.

Plasma processing is performed inside the chamber 20. The chamber 20 has a plurality of supply points 21 to which a plurality of outflow pipes 38 (described later) included in the gas supply apparatus 30 are connected. The plurality of supply points 21 includes a first supply point 21a at the central part and a second supply point 21b at the outer peripheral part. The outflow pipes 38 are each connected to a corresponding one of the first supply point 21a and the second supply point 21b. The number of the supply points 21 may be one or three or more. In addition, although there are four second supply points 21b in appearance, a plurality of supply points of the same type such as above are interpreted collectively as “one supply point”.

The gas supply apparatus 30 supplies processing gases to the chamber 20. The gas supply apparatus 30 includes a plurality of (in this example, five) supply source pipes 31, a plurality of (in this example, ten) upstream pipes 32, a plurality of (in this example, ten) flow rate controllers 33, a plurality of (in this example, twenty) midstream pipes 34, a plurality of (in this example, twenty) valves 35, a plurality of (in this example, four) downstream pipes 36, a plurality of (in this example, two) outflow pipes 38, and a control unit 39.

The plurality of supply source pipes 31 are connected to a non-illustrated gas source, and the processing gases (first to fifth processing gases) supplied from the gas source flow therethrough. The plurality of supply source pipes 31 include a first supply source pipe 31a through which the first processing gas flows, a second supply source pipe 31b through which the second processing gas flows, a third supply source pipe 31c through which the third processing gas flows, a fourth supply source pipe 31d through which the fourth processing gas flows, and a fifth supply source pipe 31e through which the fifth processing gas flows. The number of the supply source pipes 31 may be four or less, or six or more.

For example, the first processing gas may be C₄F₈; the second processing gas may be SF₆; the third processing gas may be O₂; the fourth processing gas may be Ar; and the fifth processing gas may be CF₄. However, the type of each processing gas can be arbitrarily set, other than the ones listed above.

The plurality of upstream pipes 32 are branched from the corresponding supply source pipes 31. The plurality of upstream pipes 32 correspond to the plurality of supply points 21 in the chamber 20. The plurality of upstream pipes 32 includes first to tenth upstream pipes 32a to 32j.

The first upstream pipe 32a is branched from the first supply source pipe 31a and corresponds to the first supply point 21a. The second upstream pipe 32b is branched from the first supply source pipe 31a and corresponds to the second supply point 21b.

The third upstream pipe 32c is branched from the second supply source pipe 31b and corresponds to the first supply point 21a. The fourth upstream pipe 32d is branched from the second supply source pipe 31b and corresponds to the second supply point 21b.

The fifth upstream pipe 32e is branched from the third supply source pipe 31c and corresponds to the first supply point 21a. The sixth upstream pipe 32f is branched from the third supply source pipe 31c and corresponds to the second supply point 21b.

The seventh upstream pipe 32g is branched from the fourth supply source pipe 31d and corresponds to the first supply point 21a. The eighth upstream pipe 32h is branched from the fourth supply source pipe 31d and corresponds to the second supply point 21b.

The ninth upstream pipe 32i is branched from the fifth supply source pipe 31e and corresponds to the first supply point 21a. The tenth upstream pipe 32j is branched from the fifth supply source pipe 31e and corresponds to the second supply point 21b.

The plurality of flow rate controllers 33 are provided in the respective upstream pipes 32. The flow rate controllers 33 of the present embodiment are each composed of a mass flow rate controller (MFC), but are not limited thereto. The plurality of flow rate controllers 33 include first to tenth flow rate controllers 33a to 33j.

The first flow rate controller 33a is provided at the first upstream pipe 32a to control the flow rate of the first processing gas flowing through the first upstream pipe 32a. The second flow rate controller 33b is provided at the second upstream pipe 32b to control the flow rate of the first processing gas flowing through the second upstream pipe 32b.

The third flow rate controller 33c is provided at the third upstream pipe 32c to control the flow rate of the second processing gas flowing through the third upstream pipe 32c. The fourth flow rate controller 33d is provided at the fourth upstream pipe 32d to control the flow rate of the second processing gas flowing through the fourth upstream pipe 32d.

The fifth flow rate controller 33e is provided at the fifth upstream pipe 32e to control the flow rate of the third processing gas flowing through the fifth upstream pipe 32e. The sixth flow rate controller 33f is provided at the sixth upstream pipe 32f to control the flow rate of the third processing gas flowing through the sixth upstream pipe 32f.

The seventh flow rate controller 33g is provided at the seventh upstream pipe 32g to control the flow rate of the fourth processing gas flowing through the seventh upstream pipe 32g. The eighth flow rate controller 33h is provided at the eighth upstream pipe 32h to control the flow rate of the fourth processing gas flowing through the eighth upstream pipe 32h.

The ninth flow rate controller 33i is provided at the ninth upstream pipe 32i to control the flow rate of the fifth processing gas flowing through the ninth upstream pipe 32i. The tenth flow rate controller 33j is provided at the tenth upstream pipe 32j to control the flow rate of the fifth processing gas flowing through the tenth upstream pipe 32j.

The plurality of midstream pipes 34 are branched from the corresponding upstream pipes 32. The plurality of midstream pipes 34 correspond to a plurality of (in this example, two) processing steps performed in the chamber 20. The plurality of midstream pipes 34 include first to twentieth midstream pipes 34a to 34t.

The first midstream pipe 34a is branched from the first upstream pipe 32a and corresponds to the first processing step. The second midstream pipe 34b is branched from the first upstream pipe 32a and corresponds to the second processing step.

The third midstream pipe 34c is branched from the second upstream pipe 32b and corresponds to the first processing step. The fourth midstream pipe 34d is branched from the second upstream pipe 32b and corresponds to the second processing step.

The fifth midstream pipe 34e is branched from the third upstream pipe 32c and corresponds to the first processing step. The sixth midstream pipe 34f is branched from the third upstream pipe 32c and corresponds to the second processing step.

The seventh midstream pipe 34g is branched from the fourth upstream pipe 32d and corresponds to the first processing step. The eighth midstream pipe 34h is branched from the fourth upstream pipe 32d and corresponds to the second processing step.

The ninth midstream pipe 34i is branched from the fifth upstream pipe 32e and corresponds to the first processing step. The tenth midstream pipe 34j is branched from the fifth upstream pipe 32e and corresponds to the second processing step.

The eleventh midstream pipe 34k is branched from the sixth upstream pipe 32f and corresponds to the first processing step. The twelfth midstream pipe 341 is branched from the sixth upstream pipe 32f and corresponds to the second processing step.

The thirteenth midstream pipe 34m is branched from the seventh upstream pipe 32g and corresponds to the first processing step. The fourteenth midstream pipe 34n is branched from the seventh upstream pipe 32g and corresponds to the second processing step.

The fifteenth midstream pipe 340 is branched from the eighth upstream pipe 32h and corresponds to the first processing step. The sixteenth midstream pipe 34p is branched from the eighth upstream pipe 32h and corresponds to the second processing step.

The seventeenth midstream pipe 34q is branched from the ninth upstream pipe 32i and corresponds to the first processing step. The eighteenth midstream pipe 34r is branched from the ninth upstream pipe 32i and corresponds to the second processing step.

The nineteenth midstream pipe 34s is branched from the tenth upstream pipe 32j and corresponds to the first processing step. The twentieth midstream pipe 34t is branched from the tenth upstream pipe 32j and corresponds to the second processing step.

The plurality of valves 35 are provided in the corresponding midstream pipes 34. The valves 35 of the present embodiment are each composed of an openable and closable solenoid valve, but is not limited thereto. The plurality of valves 35 include first to twentieth valve 35a to 35t.

The first valve 35a is provided in the first midstream pipe 34a to allow and stop the flow of the first processing gas in the first midstream pipe 34a. The second valve 35b is provided in the second midstream pipe 34b to allow or stop the flow of the first processing gas in the second midstream pipe 34b. The third valve 35c is provided in the third midstream pipe 34c to allow and stop the flow of the first processing gas in the third midstream pipe 34c. The fourth valve 35d is provided in the fourth midstream pipe 34d to allow and stop the flow of the first processing gas in the fourth midstream pipe 34d.

The fifth valve 35e is provided in the fifth midstream pipe 34e to allow and stop the flow of the second processing gas in the fifth midstream pipe 34e. The sixth valve 35f is provided in the sixth midstream pipe 34f to allow and stop the flow of the second processing gas in the sixth midstream pipe 34f. The seventh valve 35g is provided in the seventh midstream pipe 34g to allow and stop the flow of the second processing gas in the seventh midstream pipe 34g. The eighth valve 35h is provided in the eighth midstream pipe 34h to allow and stop the flow of the second processing gas in the eighth midstream pipe 34h.

The ninth valve 35i is provided in the ninth midstream pipe 34i to allow and stop the flow of the third processing gas in the ninth midstream pipe 34i. The tenth valve 35j is provided in the tenth midstream pipe 34j to allow and stop the flow of the third processing gas in the tenth midstream pipe 34j. The eleventh valve 35k is provided in the eleventh midstream pipe 34k to allow and stop the flow of the third processing gas in the eleventh midstream pipe 34k. The twelfth valve 351 is provided in the twelfth midstream pipe 341 to allow and stop the flow of the third processing gas in the twelfth midstream pipe 34l.

The thirteenth valve 35m is provided in the thirteenth midstream pipe 34m to allow and stop the flow of the fourth processing gas in the thirteenth midstream pipe 34m. The fourteenth valve 35n is provided in the fourteenth midstream pipe 34n to allow and stop the flow of the fourth processing gas in the fourteenth midstream pipe 34n. The fifteenth valve 350 is provided in the fifteenth midstream pipe 34o to allow and stop the flow of the fourth processing gas in the fifteenth midstream pipe 34o. The sixteenth valve 35p is provided in the sixteenth midstream pipe 34p to allow and stop the flow of the fourth processing gas in the sixteenth midstream pipe 34p.

The seventeenth valve 35q is provided in the seventeenth midstream pipe 34q to allow and stop the flow of the fifth processing gas in the seventeenth midstream pipe 34q. The eighteenth valve 35r is provided in the eighteenth midstream pipe 34r to allow and stop the flow of the fifth processing gas in the eighteenth midstream pipe 34r. The nineteenth valve 35s is provided in the nineteenth midstream pipe 34s to allow and stop the flow of the fifth processing gas in the nineteenth midstream pipe 34s. The twentieth valve 35t is provided in the twentieth midstream pipe 34t to allow and stop the flow of the fifth processing gas in the twentieth midstream pipe 34t.

Midstream pipes 34 corresponding to the same supply point 21 and the same processing step merge into a corresponding one of the plurality of downstream pipes 36. The plurality of downstream pipes 36 include first to fourth downstream pipes 36a to 36d.

The first midstream pipe 34a, the fifth midstream pipe 34e, the ninth midstream pipe 34i, the thirteenth midstream pipe 34m, and the seventeenth midstream pipe 34q merge into the first downstream pipe 36a. Any combination of the first through fifth processing gases is flowable in the first downstream pipe 36a.

The second midstream pipe 34b, the sixth midstream pipe 34f, the tenth midstream pipe 34j, the fourteenth midstream pipe 34n, and the eighteenth midstream pipe 34r merge into the second downstream pipe 36b. Any combination of the first through fifth processing gases is flowable in the second downstream pipe 36b.

The third midstream pipe 34c, the seventh midstream pipe 34g, the eleventh midstream pipe 34k, the fifteenth midstream pipe 340, and the nineteenth midstream pipe 34s merge into the third downstream pipe 36c. Any combination of the first through fifth processing gases is flowable in the third downstream pipe 36c.

The fourth midstream pipe 34d, the eighth midstream pipe 34h, the twelfth midstream pipe 341, the sixteenth midstream pipe 34p, and the twentieth midstream pipe 34t merge into the fourth downstream pipe 36d. Any combination of the first through fifth processing gases is flowable in the fourth downstream pipe 36d.

The plurality of outflow pipes 38 are each connected to a downstream pipe 36 corresponding to the same supply point 21 through a switching section 37 (a first switching section 37a or a second switching section 37b). Each of the plurality of outflow pipes 38 is connected to one of the supply points 21. The plurality of outflow pipes 38 include a first outflow pipe 38a and a second outflow pipe 38b.

The first outflow pipe 38a is connected to either the first downstream pipe 36a or the second downstream pipe 36b through the first switching section 37a, and is connected to the first supply point 21a. The first switching section 37a is composed of a first switching valve 37a that causes either the first downstream pipe 36a or the second downstream pipe 36b to be in exclusive fluid communication with the first outflow pipe 38a.

The second outflow pipe 38b is connected to either the third downstream pipe 36c or the fourth downstream pipe 36d through the second switching section 37b, and is connected to the second supply point 21b. The second outflow pipe 38b of the present embodiment is branched in the middle into, but is not limited to, four pipes, each of which is connected to a corresponding second supply point 21b. The second switching section 37b is composed of a second switching valve 37b that causes either the third downstream pipe 36c or the fourth downstream pipe 36d to be in exclusive fluid communication with the second outflow pipe 38b.

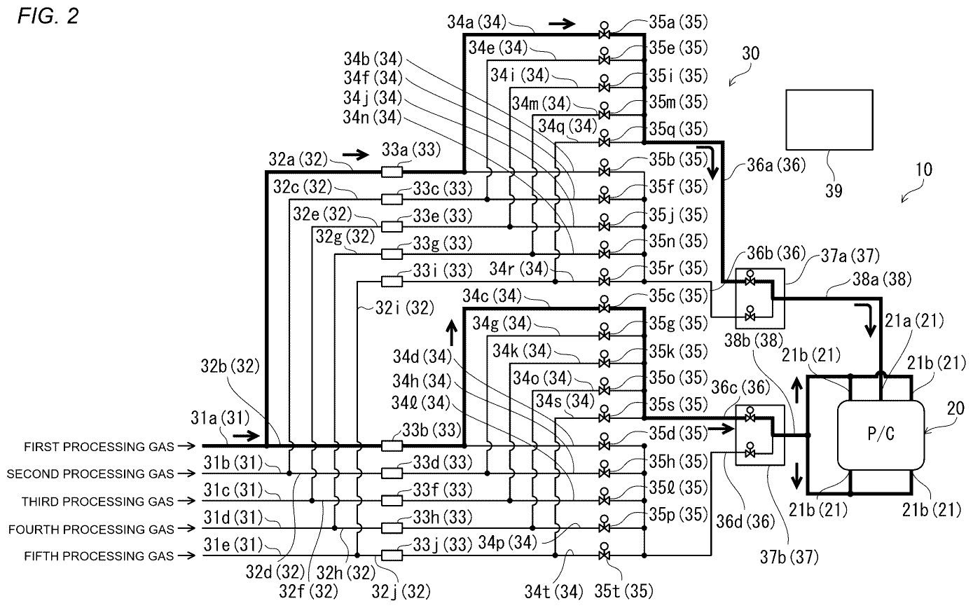

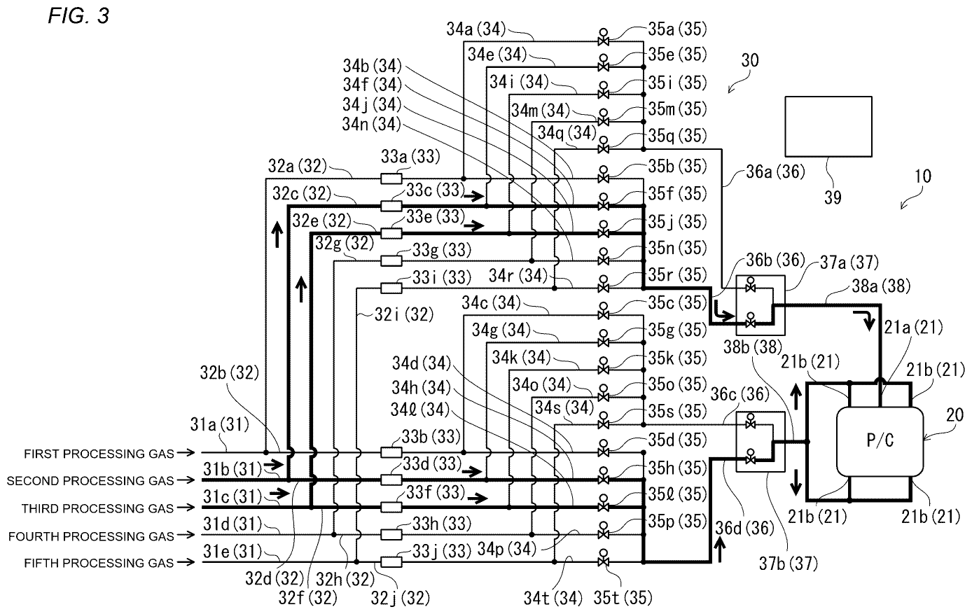

The control unit 39 controls the switching section 37 so that the downstream pipes 36 in fluid communication with the plurality of outflow pipes 38 are switched according to the processing steps. The control unit 39 executes first control illustrated in FIG. 2 (i.e., first control corresponding to the first processing step) and second control illustrated in FIG. 3 (i.e., second control corresponding to the second processing step). In FIGS. 2 and 3, the flows of the processing gases are indicated by thick solid lines and arrows. The control unit 39 may be incorporated in a non-illustrated control device included in the plasma processing apparatus 10, or may be provided separately from the control device.

Under the first control in the present embodiment, the control unit 39 causes the first downstream pipe 36a and the first outflow pipe 38a to be in fluid communication with each other through the first switching valve 37a, and causes the third downstream pipe 36c and the second outflow pipe 38b to be in fluid communication with each other through the second switching valve 37b. Under the first control in the present embodiment, the control unit 39 opens the first valve 35a and the third valve 35c, and closes the second valve 35b and the fourth to twentieth valves 35d to 35t. Under the first control in the present embodiment, the control unit 39 performs opening degree control of the first flow rate controller 33a and the second flow rate controller 33b, and sets the third to tenth flow rate controllers 33c to 33j to the closed state.

Under the first control in the present embodiment, the first processing gas (in this example, C₄F₈) flows through the first supply source pipe 31a, the first upstream pipe 32a, the first midstream pipe 34a, the first downstream pipe 36a, and the first outflow pipe 38a in the stated order and flows out to the first supply point 21a of the chamber 20. Under the first control in the present embodiment, the first processing gas flows through the first supply source pipe 31a, the second upstream pipe 32b, the third midstream pipe 34c, the third downstream pipe 36c, and the second outflow pipe 38b in the stated order and flows out to the second supply point 21b of the chamber 20. That is, under the first control in the present embodiment, the first processing gas is supplied to the chamber 20 by the gas supply apparatus 30.

Under the second control in the present embodiment, the control unit 39 causes the second downstream pipe 36b and the first outflow pipe 38a to be in fluid communication with each other through the first switching valve 37a, and causes the fourth downstream pipe 36d and the second outflow pipe 38b to be in fluid communication with each other through the second switching valve 37b. Under the second control in the present embodiment, the control unit 39 opens the sixth valve 35f, the eighth valve 35h, the tenth valve 35j, and the twelfth valve 35l, and closes the first to fifth valves 35a to 35e, the seventh valve 35g, the ninth valve 35i, the eleventh valve 35k, and the thirteenth to twentieth valves 35m to 35t. Under the second control in the present embodiment, the control unit 39 performs opening degree control of the third to sixth flow rate controllers 33c to 33f, and sets the first and second flow rate controllers 33a and 33b and the seventh to tenth flow rate controllers 33g to 33j to the closed state.

Under the second control in the present embodiment, the second processing gas (in this example, SF₆) flows through the second supply source pipe 31b, the third upstream pipe 32c, the sixth midstream pipe 34f, the second downstream pipe 36b, and the first outflow pipe 38a in the stated order and flows out to the first supply point 21a of the chamber 20. Under the second control in the present embodiment, the second processing gas flows through the second supply source pipe 31b, the fourth upstream pipe 32d, the eighth midstream pipe 34h, the fourth downstream pipe 36d, and the second outflow pipe 38b in the stated order and flows out to the second supply point of the chamber 20. Under the second control in the present embodiment, the third processing gas (in this example, O₂) flows through the third supply source pipe 31c, the fifth upstream pipe 32e, the tenth midstream pipe 34j, the second downstream pipe 36b, and the first outflow pipe 38a in the stated order and flows out to the first supply point 21a of the chamber 20. Further, under the second control in the present embodiment, the third processing gas flows through the third supply source pipe 31c, the sixth upstream pipe 32f, the twelfth midstream pipe 341, the fourth downstream pipe 36d, and the second outflow pipe 38b in the stated order and flows out to the second supply point 21b of the chamber 20. That is, under the second control in the present embodiment, the mixed gas of the second processing gas and the third processing gas is supplied to the chamber 20 by the gas supply apparatus 30.

In the present embodiment, the control unit 39 repeats a unit process including the first control and the second control multiple times. For example, the first control and the second control may be alternately executed multiple times. Thus, plasma etching by a Bosch process can be performed on a substrate (not illustrated) placed in the chamber 20. When the control is switched between the first control and the second control, the connection states of the first switching valve 37a and the second switching valve 37b are switched. At switching, only a small amount of the processing gas remains between the chamber 20 and the switching valves 37a and 37b (i.e., in the first or second outflow pipe 38a or 38b) because both the switching valves 37a,37b are located near the chamber 20. Therefore, the processing gas having been supplied to the chamber 20 before the switching and the processing gas supplied to the chamber 20 after the switching hardly mix in switching between the first control and the second control, and thus switching between the processing gases can be done at high speed. The number of times the control unit 39 repeats the unit process is not particularly limited.

### Supplemental Remarks

According to the above description of the embodiment, the following techniques are disclosed.

### Technique 1

A gas supply apparatus including:
a plurality of supply source pipes through which processing gases flows;
a plurality of upstream pipes branched from the supply source pipes and corresponding to a plurality of supply points in the chamber;
a plurality of flow rate controllers provided in the respective upstream pipes;
a plurality of midstream pipes branched from the upstream pipes and corresponding to a plurality of processing steps performed in the chamber;
a plurality of valves provided in the respective midstream pipes;
a plurality of downstream pipes into which midstream pipes of the midstream pipes corresponding to a same supply point of the supply points and a same processing step of the processing steps merge;
a plurality of outflow pipes connected to downstream pipes of the downstream pipes corresponding to a same supply point of the supply points through a switching section, the outflow pipes each being connected to one of the supply points; and
a control unit that controls the switching section so that downstream pipes of the downstream pipes in fluid communication with the plurality of outflow pipes are switched according to the processing steps.

### Technique 2

The gas supply apparatus according to Technique 1, wherein
the plurality of supply source pipes include:
   a first supply source pipe through which a first processing gas of the processing gases flows; and
   a second supply source pipe through which a second process of the processing gases flows,
the plurality of upstream pipes include:
   a first upstream pipe and second upstream pipe each branched from the first supply source pipe, and respectively corresponding to a first supply point and a second supply point of the supply points; and
   a third upstream pipe and a fourth upstream pipe each branched from the second supply source pipe, and respectively corresponding to the first supply point and the second supply point,
the plurality of flow rate controllers include:
   a first flow rate controller provided at the first upstream pipe;
   a second flow rate controller provided at the second upstream pipe;
   a third flow rate controller provided at the third upstream pipe; and
   a fourth flow rate controller provided at the fourth upstream pipe,
the plurality of midstream pipes include:
   a first midstream pipe and a second midstream pipe each branched from the first upstream pipe, and respectively corresponding to a first processing step and a second processing step of the processing steps;
   a third midstream pipe and a fourth midstream pipe each branched from the second upstream pipe, and respectively corresponding to the first processing step and the second processing step;
   a fifth midstream pipe and a sixth midstream pipe each branched from the third upstream pipe, and respectively corresponding to the first processing step and the second
   a seventh midstream pipe and an eighth midstream pipe each branched from the fourth upstream pipe, and respectively corresponding to the first processing step and the second processing step,
the plurality of valves include:
   a first valve provided in the first midstream pipe;
   a second valve provided in the second midstream pipe;
   a third valve provided in the third midstream pipe;
   a fourth valve provided in the fourth midstream pipe;
   a fifth valve provided in the fifth midstream pipe;
   a sixth valve provided in the sixth midstream pipe;
   a seventh valve provided in the seventh midstream pipe; and
   an eighth valve provided in the eighth midstream pipe,
the plurality of downstream pipes include:
   a first downstream pipe into which the first midstream pipe and the fifth midstream pipe merge;
   a second downstream pipe into which the second midstream pipe and the sixth midstream pipe merge;
   a third downstream pipe into which the third midstream pipe and the seventh midstream pipe merge; and
   a fourth downstream pipe into which the fourth midstream pipe and the eighth midstream pipe merge,
the plurality of outflow pipes includes:
   a first outflow pipe connected to either the first downstream pipe or the second downstream pipe through a first switching section of the switching section, and connected to the first supply point; and
   a second outflow pipe connected to either the third downstream pipe or the fourth downstream pipe through a second switching section of the switching section, and connected to the second supply point,
   the first switching section is composed of a first switching valve that causes either the first downstream pipe or the second downstream pipe to be in exclusive fluid communication with the first outflow pipe,
the second switching section is composed of a second switching valve that causes either the third downstream pipe or the fourth downstream pipe to be in exclusive fluid communication with the second outflow pipe, and
the control unit executes:
   first control under which: the first downstream pipe and the first outflow pipe are in fluid communication with each other through the first switching valve; the third downstream pipe and the second outflow pipe are in fluid communication with each other through the second switching valve; and the second valve, the fourth valve, the sixth valve, and the eighth valve are closed; and
   second control under which: the second downstream pipe and the first outflow pipe are in fluid communication with each other through the first switching valve; the fourth downstream pipe and the second outflow pipe are in fluid communication with each other through the second switching valve; and the first valve, the third valve, the fifth valve, and the seventh valve are closed.

### Technique 3

The gas supply apparatus according to Technique 2, wherein the control unit repeats a unit process including the first control and the second control multiple times.

### Technique 4

A plasma processing apparatus including:
a chamber in which plasma processing is performed; and
the gas supply apparatus according to any one of Techniques 1 to 3, wherein
the gas supply apparatus supplying the processing gases to the chamber.

The present disclosure can be used for gas supply apparatuses and plasma processing apparatuses.

### REFERENCE NUMERALS

10: Plasma processing apparatus
   20: Chamber
      21: Supply point
         21a, 21b: First and second supply points
30: Gas supply apparatus
   31: Supply source pipe
      31a to 31e: First to fifth supply source pipes
   32: Upstream pipe
      32a to 32j: First to tenth upstream pipes
   33: Flow rate controller
      33a to 33j: First to tenth flow rate controllers
   34: Midstream pipe
      34a to 34t: First to twentieth midstream pipes
   35: Valve
      35a to 35t: First to twentieth valves
   36: Downstream pipe
      36a to 36d: first to fourth downstream pipes
   37: Switching section
      37a: First switching section (first switching valve)
      37b: Second switching section (second switching valve)
   38: Outflow pipe
      38a, 38b: First and second outflow pipes
   39: Control unit

1. A gas supply apparatus comprising:
a plurality of supply source pipes through which processing gases flows;
a plurality of upstream pipes branched from the supply source pipes and corresponding to a plurality of supply points in the chamber;
a plurality of flow rate controllers provided in the respective upstream pipes;
a plurality of midstream pipes branched from the upstream pipes and corresponding to a plurality of processing steps performed in the chamber;
a plurality of valves provided in the respective midstream pipes;
a plurality of downstream pipes into which midstream pipes of the midstream pipes corresponding to a same supply point of the supply points and a same processing step of the processing steps merge;
a plurality of outflow pipes connected to downstream pipes of the downstream pipes corresponding to a same supply point of the supply points through a switching section, the outflow pipes each being connected to one of the supply points; and
a control unit that controls the switching section so that downstream pipes of the downstream pipes in fluid communication with the plurality of outflow pipes are switched according to the processing steps.

2. The gas supply apparatus according to claim 1, wherein
the plurality of supply source pipes include:
a first supply source pipe through which a first processing gas of the processing gases flows; and
a second supply source pipe through which a second process of the processing gases flows,
the plurality of upstream pipes include:
a first upstream pipe and second upstream pipe each branched from the first supply source pipe, and respectively corresponding to a first supply point and a second supply point of the supply points; and
a third upstream pipe and a fourth upstream pipe each branched from the second supply source pipe, and respectively corresponding to the first supply point and the second supply point,
the plurality of flow rate controllers include:
a first flow rate controller provided at the first upstream pipe;
a second flow rate controller provided at the second upstream pipe;
a third flow rate controller provided at the third upstream pipe; and
a fourth flow rate controller provided at the fourth upstream pipe,
the plurality of midstream pipes include:
a first midstream pipe and a second midstream pipe each branched from the first upstream pipe, and respectively corresponding to a first processing step and a second processing step of the processing steps;
a third midstream pipe and a fourth midstream pipe each branched from the second upstream pipe, and respectively corresponding to the first processing step and the second processing step;
a fifth midstream pipe and a sixth midstream pipe each branched from the third upstream pipe, and respectively corresponding to the first processing step and the second processing step; and
a seventh midstream pipe and an eighth midstream pipe each branched from the fourth upstream pipe, and respectively corresponding to the first processing step and the second processing step,
the plurality of valves include:
a first valve provided in the first midstream pipe;
a second valve provided in the second midstream pipe;
a third valve provided in the third midstream pipe;
a fourth valve provided in the fourth midstream pipe;
a fifth valve provided in the fifth midstream pipe;
a sixth valve provided in the sixth midstream pipe;
a seventh valve provided in the seventh midstream pipe; and
an eighth valve provided in the eighth midstream pipe,
the plurality of downstream pipes include:
a first downstream pipe into which the first midstream pipe and the fifth midstream pipe merge;
a second downstream pipe into which the second midstream pipe and the sixth midstream pipe merge;
a third downstream pipe into which the third midstream pipe and the seventh midstream pipe merge; and
a fourth downstream pipe into which the fourth midstream pipe and the eighth midstream pipe merge,
the plurality of outflow pipes includes:
a first outflow pipe connected to either the first downstream pipe or the second downstream pipe through a first switching section of the switching section, and connected to the first supply point; and
a second outflow pipe connected to either the third downstream pipe or the fourth downstream pipe through a second switching section of the switching section, and connected to the second supply point,
the first switching section is composed of a first switching valve that causes either the first downstream pipe or the second downstream pipe to be in exclusive fluid communication with the first outflow pipe,
the second switching section is composed of a second switching valve that causes either the third downstream pipe or the fourth downstream pipe to be in exclusive fluid communication with the second outflow pipe, and
the control unit executes:
first control under which: the first downstream pipe and the first outflow pipe are in fluid communication with each other through the first switching valve; the third downstream pipe and the second outflow pipe are in fluid communication with each other through the second switching valve; and the second valve, the fourth valve, the sixth valve, and the eighth valve are closed; and
second control under which: the second downstream pipe and the first outflow pipe are in fluid communication with each other through the first switching valve; the fourth downstream pipe and the second outflow pipe are in fluid communication with each other through the second switching valve; and the first valve, the third valve, the fifth valve, and the seventh valve are closed.

3. The gas supply apparatus according to claim 2, wherein
the control unit repeats a unit process including the first control and the second control multiple times.

4. A plasma processing apparatus comprising:
a chamber in which plasma processing is performed; and
the gas supply apparatus according to claim 1, the gas supply apparatus supplying the processing gases to the chamber.

5. A plasma processing apparatus comprising:
a chamber in which plasma processing is performed; and
the gas supply apparatus according to claim 2, the gas supply apparatus supplying the processing gases to the chamber.

6. A plasma processing apparatus comprising:
a chamber in which plasma processing is performed; and
the gases supply apparatus according to claim 3, the gas supply apparatus supplying the processing gases to the chamber.
